(19) United States
(12) Patent Application Publication
(10) Pub. No.: US 2007/0170558 A1
(43) Pub. Date: Jul. 26, 2007

(54) STACKED INTEGRATED CIRCUIT PACKAGE SYSTEM

(76) Inventors: Zigmund Ramirez Camacho, Singapore (SG); Wong Sze Min, Singapore (SG); Arnel Trasporto, Singapore (SG); Jeffrey D. Punzalan, Singapore (SG)

Correspondence Address: ISHIMARU & ZAHRT LLP, 333 W. EL CAMINO REAL, SUITE 330, SUNNYVALE, CA, 94087, US

(21) Appl. No.: 11/307,101

(22) Filed: Jan. 24, 2006

(51) Int. Cl. H01L 23/495

(52) U.S. Cl. 257/676

(57) ABSTRACT

A stacked integrated circuit package system is provided providing a lead frame having a die paddle, attaching a first integrated circuit on the die paddle of the lead frame, connecting first electrical interconnects between the first integrated circuit and the lead frame, encapsulating the first integrated circuit and the first electrical interconnects, attaching a second integrated circuit on the die paddle of the first integrated circuit, connecting second electrical interconnects between the second integrated circuit and the lead frame, and encapsulating the second integrated circuit and the second electrical interconnects.

### TECHNICAL FIELD

The present invention relates generally to integrated circuit packages and more particularly to stacked integrated circuit packages.

### BACKGROUND ART

Modern consumer electronics, such as cellular phones, digital cameras, and music players, are packing more integrated circuits into an ever shrinking physical space with expectations for decreasing cost. Numerous technologies have been developed to meet these requirements. Some of the research and development strategies focus on new package technologies while others focus on improving the existing and mature package technologies. Research and development in the existing package technologies may take a myriad of different directions.

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for lower height, smaller space, and cost reduction.

One proven way to reduce cost is to use mature package technologies with existing manufacturing methods and equipments. Paradoxically, the reuse of existing manufacturing processes does not typically result in the reduction of package dimensions.

Thus, a need still remains for a stacked integrated circuit package system providing low cost manufacturing as well as reduce the integrated circuit package dimensions. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a stacked integrated circuit package system including providing a lead frame having a die paddle, attaching a first integrated circuit on the die paddle of the lead frame, connecting first electrical interconnects between the first integrated circuit and the lead frame, encapsulating the first integrated circuit and the first electrical interconnects, attaching a second integrated circuit on the die paddle of the first integrated circuit, connecting second electrical interconnects between the second integrated circuit and the lead frame, and encapsulating the second integrated circuit and the second electrical interconnects.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of a stacked integrated circuit package system in an embodiment of the present invention;

FIG. 2 is a cross-sectional view of the stacked integrated circuit package system in a first die-attach phase;

FIG. 3 is a cross-sectional view of the stacked integrated circuit package system in a second die-attach phase;

FIG. 4 is a cross-sectional view of the stacked integrated circuit package system in a second encapsulation phase; and

FIG. 5 is a flow chart of a system for a stacked integrated circuit package system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. The same numbers are used in all the figures to relate to the same elements.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means that there is direct contact among elements.

The term “processing” as used herein includes deposition of material, patterning, exposure, development, etching, cleaning, molding, and/or removal of the material or as required in forming a described structure.

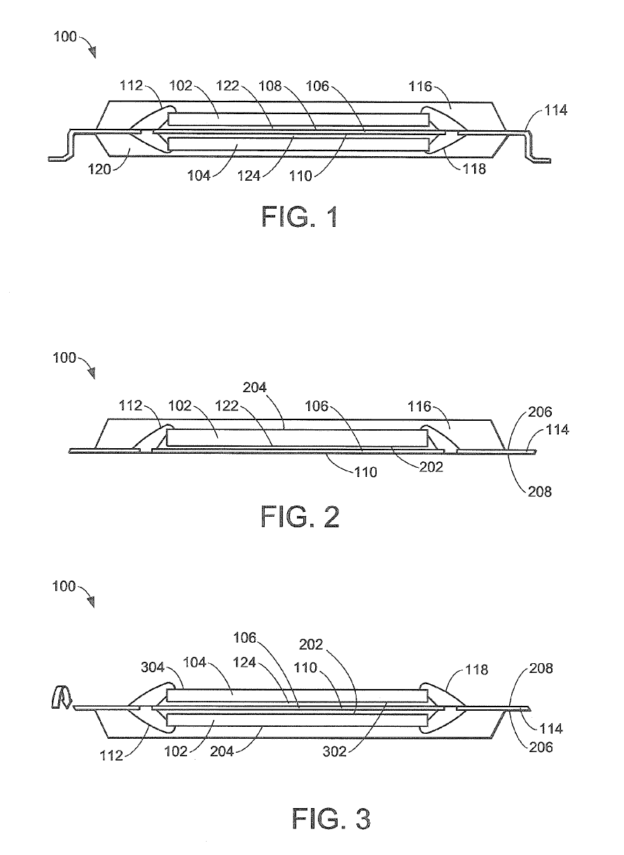

Referring now to FIG. 1, therein is shown a cross-sectional view of a stacked integrated circuit package system 100 in an embodiment of the present invention. The stacked integrated circuit package system 100 includes a first integrated circuit 102 above a second integrated circuit 104 with a die paddle 106. The die paddle 106 includes a top paddle surface 108 and a bottom paddle surface 110, and is between the first integrated circuit 102 and the second integrated circuit 104.

First electrical interconnects 112, such as bond wires, connect the first integrated circuit 102 to lead fingers 114. A first molding compound 116 covers the first integrated circuit 102, the top paddle surface 108, the first electrical interconnects 112, and an inner portion of the lead fingers 114.

Second electrical interconnects 118, such as bond wires, connect the second integrated circuit 104 to the lead fingers 114. A second molding compound 120 covers the second integrated circuit 104, the bottom paddle surface 110, the second electrical interconnects 118, and the inner portion of the lead fingers 114. A thickness of the second molding compound 120 is less than a height of the lead fingers 114 such that the second molding compound 120 does not impede the lead fingers 114 connecting to the next system level, such as a printed circuit board (not shown).

A first adhesive layer 122, such as an epoxy paste or adhesive film, attaches the first integrated circuit 102 to the top paddle surface 108. A second adhesive layer 124, such as an epoxy paste or adhesive film, attaches the second integrated circuit 104 to the bottom paddle surface 110. For illustrative purposes, the first integrated circuit 102 and the second integrated circuit 104 are shown similar in size, although it is understood that the size of the first integrated circuit 102 and the second integrated circuit 104 may differ, as well. Also for illustrative purposes, the first molding compound 116 and the second molding compound 120 are shown as different materials, although it is understood that the first molding compound 116 and the second molding compound 120 may not be different materials.

Also for illustrative purposes, the first electrical interconnects 112 are shown connecting the first integrated circuit 102 to the lead fingers 114, although it is understood that the first electrical interconnects 112 may connect the first integrated circuit 102 to the die paddle 106 or to both the lead fingers 114 and the die paddle 106. Again for illustrative purposes, the second electrical interconnects 118 are shown connecting the second integrated circuit 104 to the lead fingers 114, although it is understood that the second electrical interconnects 118 may connect the second integrated circuit 104 to the die paddle 106 or to both the lead fingers 114 and the die paddle 106.

Further for illustrative purpose, the first integrated circuit 102 and the second integrated circuit 118 are shown stacked in a back-to-back configuration, although it is understood that the first integrated circuit 102 and the second integrated circuit 118 may each represent a stack of integrated circuits (not shown). Again for illustrative purpose, the first integrated circuit 102 and the second integrated circuit 118 are shown stacked in a back-to-back configuration, although it is understood that any number of integrated circuits (not shown) may be stacked in the back-to-back configuration to the first integrated circuit 102 or the second integrated circuit 118, or both.

Referring now to FIG. 2, therein is shown a cross-sectional view of the stacked integrated circuit package system 100 in a first die-attach phase. The first integrated circuit 102 includes a first back side 202 and a first active side 204, wherein the first active side 204 has circuitry fabricated thereon. The lead frame (not shown) includes the lead fingers 114, wherein the lead fingers 114 have a top surface 206 and a bottom surface 208.

The first integrated circuit 102 is attached by the first back side 202 to the die paddle 106 by the first adhesive layer 122. The die paddle 106 and the first adhesive layer 122 provide planar support substantially securing the first integrated circuit 102. The first electrical interconnects 112 electrically connect the first active side 204 of the first integrated circuit 102 to the top surface 206 of the lead fingers 114, as required.

The first molding compound 116 encapsulates the first integrated circuit 102, the top paddle surface 108, of the die paddle 106, the first electrical interconnects 112, the first adhesive layer 122 and the inner portion of the top surface 206 of the lead fingers 114. The first molding compound 116 protects and substantially secures the locations of the first integrated circuit 102, the first electrical interconnects 112, and the lead fingers 114. The molding process leaves the bottom paddle surface 110 and the bottom surface 208, of the lead fingers 114, clean and exposed for further processing.

Referring now to FIG. 3, therein is shown a cross-sectional view of the stacked integrated circuit package system 100 in a second die-attach phase. The stacked integrated circuit package system 100 is in an orientation vertically flipped from the orientation shown in FIG. 2, such that the first active side 204 of the first integrated circuit 102 is oriented downwards. The first back side 202, of the first integrated circuit 102, the bottom paddle surface 110 and the bottom surface 208 of the lead fingers 114 are oriented upwards.

The second integrated circuit 104 includes a second back side 302 and a second active side 304, wherein the second active side 304 has circuitry fabricated thereon. The second adhesive layer 124 is applied to the bottom paddle surface 110, of the die paddle 106, positioned above the first integrated circuit 102. The second back side 302 of the second integrated circuit 104 is mounted on the second adhesive layer 124 above the first integrated circuit 102. The second electrical interconnects 118 connect the second active side 304 of the second integrated circuit 104 to the inner portion of the bottom surface 208 of the lead fingers 114.

The second adhesive layer 124 elevates the second back side 302 of the second integrated circuit 104 to a horizontal plane minimally above the horizontal plane of the bottom surface 208 of the inner portion of the lead fingers 114 and the bottom paddle surface 110 of the die paddle 106. The second electrical interconnects 118 are on the side opposite the first electrical interconnects 112 eliminating the possibility of crossing the second electrical interconnects 118 with the first electrical interconnects 112.

For illustrative purposes, the second adhesive layer 124 is shown applied to the bottom paddle surface 110 of the die paddle 106, although it is understood the second adhesive layer 124 may extend to the bottom surface 208 of the lead fingers 114. Also for illustrative purposes, the second electrical interconnects 118 are shown attached to the bottom surface 208 substantially vertically aligned to the first electrical interconnects 112 attached to the top surface 206, although it is understood that the contact locations on the bottom surface 208 and the top surface 206 of the second electrical interconnects 118 and the first electrical interconnects 112, respectively, may not be vertically aligned, as well.

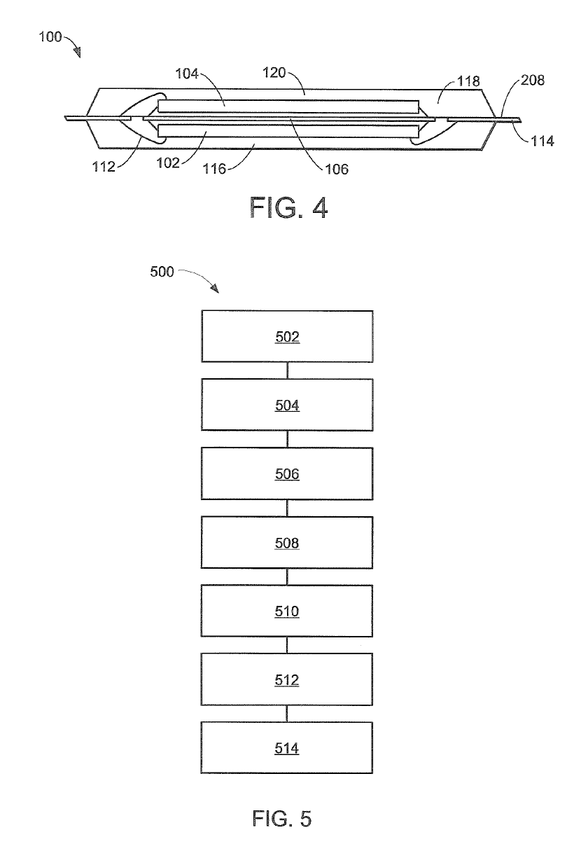

Referring now to FIG. 4, therein is shown a cross-sectional view of the stacked integrated circuit package system 100 in a second encapsulation phase. The second molding compound 120 encapsulates the second integrated circuit 104, the bottom paddle surface 110, the second electrical interconnects 118, the second adhesive layer 124, and the inner portion of the bottom surface 208 of the lead fingers 114. The second molding compound 120 attaches to the first molding compound 116 to seal the first and second integrated circuits 102 and 104. The second molding compound 120 protects the second integrated circuit 104, the second electrical interconnects 118, and the second adhesive layer 124.

The second encapsulation phase forms the stacked integrated circuit package system 100. The attachment of the second molding compound 120 to the first molding compound 116 protects and seals the stacked integrated circuit package system 100.

Referring now to FIG. 5, therein is shown a flow chart of a system 500 for a stacked integrated circuit package system 100 in an embodiment of the present invention. The system 500 includes providing a lead frame having a die paddle in a block 502; attaching a first integrated circuit on the die paddle of the lead frame in a block 504; connecting first electrical interconnects between the first integrated circuit and the lead frame in a block 506; encapsulating the first integrated circuit and the first electrical interconnects in a block 508; attaching a second integrated circuit on the die paddle of the first integrated circuit in a block 510; connecting second electrical interconnects between the second integrated circuit and the lead frame in a block 512; and encapsulating the second integrated circuit and the second electrical interconnects in a block 514.

In greater detail, a method to fabricate the stacked integrated circuit package system 100, according to an embodiment of the present invention, is performed as follows:
(1) 1. Providing the lead fingers with the die paddle. (FIG. 2)
(2) 2. Attaching the first back side of the first integrated circuit to the top paddle surface of the die paddle with the first adhesive layer . (FIG. 2)
(3) 3. Connecting the first electrical interconnects to the first active side of the first integrated circuit and the top surface of the inner portion of the lead fingers. (FIG. 2)
(4) 4. Encapsulating the first integrated circuit, the first electrical interconnects, the top paddle surface of the die paddle, and the inner portion of the top surface of the lead fingers. (FIG. 2)
(5) 5. Mounting the second back side of the second integrated circuit on the bottom paddle surface of the die paddle with a second adhesive layer above the first back side of the first integrated circuit. (FIG. 3)
(6) 6. Connecting the second electrical interconnects to the second active side of the second integrated circuit and the bottom surface of the inner portion of the lead fingers. (FIG. 3)
(7) 7. Encapsulating the second integrated circuit, the second electrical interconnects, the second adhesive layer, the bottom paddle surface of the die paddle, and the inner portion of the bottom surface of the lead fingers. (FIG. 4)

It has been discovered that the present invention thus has numerous aspects.

It has been discovered that the stacked integrated circuit package system provides a low cost manufacturing solution by simplifying handling methods, simplifying some manufacturing equipment design, alleviates the need for some stringent processes to lower cost processes, and eliminates other causes that may result in potential yield issues.

An aspect is that the present invention provides dual molding and dual sided bonding to lessen the criticality of die placement and rotation. The invention avoids additional controls for handling during both assembly process and optical inspection. Also, the invention avoids complex equipment and tooling design for die-attach and wire bond considering dual side processing with both sides still un-encapsulated.

Another aspect of the present invention is that the stacking of the integrated circuits in a back-to-back arrangement with the die paddle in between eliminates the risk of contacting the active sides of the integrated circuits during manufacturing. The back-to-back die attach eliminates the overhang from die to die thereby enabling lower package height.

Yet another aspect of the present invention is that the wire bonding at opposite sides reduces wire bonding complexity. The bond wires will not need to be staggered to minimize the potential crossing of the bond wires. Stacking the integrated circuits in a back-to-back arrangement minimizes the need for a lower loop-height and avoiding more expensive wire bonding techniques, such as reverse stitch stand-off bump (RSSB) or ultra-low loop capability for first integrated circuit bonding. The invention enables fine pitch stacked die applications on leaded packages and “same-size” (similar horizontal dimensions) die stacking for QFP packages.

Yet another important aspect of the present invention is that it valuably supports and services the historical trend of reducing costs, simplifying systems, and increasing performance. These and other valuable aspects of the present invention consequently further the state of the technology to at least the next level.

Thus, it has been discovered that the stacked integrated circuit package system method of the present invention furnishes important and heretofore unknown and unavailable solutions, capabilities, and functional aspects for increasing chip density in systems. The resulting processes and configurations are straightforward, cost-effective, uncomplicated, highly versatile and effective, can be implemented by adapting known technologies, and are thus readily suited for efficiently and economically manufacturing stacked integrated circuit packaged devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A stacked integrated circuit package system comprising:
providing a lead frame having a die paddle;
attaching a first integrated circuit on the die paddle of the lead frame;
connecting first electrical interconnects between the first integrated circuit and the lead frame;
encapsulating the first integrated circuit and the first electrical interconnects;
attaching a second integrated circuit on the die paddle below the first integrated circuit;
connecting second electrical interconnects between the second integrated circuit and the lead frame; and
encapsulating the second integrated circuit and the second electrical interconnects.

2. The system as claimed in claim 1 further comprising attaching a first back side of the first integrated circuit to a top paddle surface of the die paddle and a second back side of the second integrated circuit to a bottom paddle surface of the die paddle.

3. The system as claimed in claim 1 wherein attaching the first integrated circuit on the die paddle comprises applying a first adhesive layer between a first back side of the first integrated circuit and the die paddle.

4. The system as claimed in claim 1 wherein attaching the second integrated circuit on the die paddle comprises applying a second adhesive layer between a second back side of the second integrated circuit and the die paddle.

5. The system as claimed in claim 1 wherein encapsulating the second integrated circuit includes sealing the first and second integrated circuits.

6. A stacked integrated circuit package system comprising: providing lead fingers and a die paddle;
attaching a first back side of a first integrated circuit on a top paddle surface of the die paddle;
connecting first electrical interconnects between a first active side of the first integrated circuit and a top surface of the inner portion of the lead fingers;
encapsulating the first integrated circuit, the first electrical interconnects, the top paddle surface, and the top surface of the lead fingers;
attaching a second back side of a second integrated circuit on a bottom paddle surface of the die paddle;
connecting second electrical interconnects between a second active side of the second integrated circuit and a bottom surface of the inner portion of the lead fingers; and
encapsulating the second integrated circuit, the second electrical interconnects, the bottom paddle surface, and the bottom surface of the lead fingers.

7. The system as claimed in claim 6 further comprising forming horizontal dimensions of the first integrated circuit similar to horizontal dimension of the second integrated circuit.

8. The system as claimed in claim 6 wherein encapsulating the second molding compound comprises forming a thickness of the second molding compound less than a height of the lead fingers.

9. The system as claimed in claim 6 wherein connecting the first electrical interconnects comprises connecting bond wires.

10. The system as claimed in claim 6 wherein connecting the second electrical interconnects comprises connecting bond wires.

11. A stacked integrated circuit package system comprising:
a lead frame having a die paddle;
a first integrated circuit on the die paddle of the lead frame;
first electrical interconnects between the first integrated circuit and the lead frame;
a first molding compound to cover the first integrated circuit and the first electrical interconnects;
a second integrated circuit on the die paddle below the first integrated circuit;
second electrical interconnects between the second integrated circuit and the lead frame; and
a second molding compound to cover the second integrated circuit and the second electrical interconnects.

12. The system as claimed in claim 11 further comprising a first back side of the first integrated circuit to a top paddle surface of the die paddle and a second back side of the second integrated circuit to a bottom paddle surface of the die paddle.

13. The system as claimed in claim 11 wherein the first integrated circuit on the die paddle comprises a first adhesive layer between a first back side of the first integrated circuit and the die paddle.

14. The system as claimed in claim 11 wherein the second integrated circuit on the die paddle comprises a second adhesive layer between a second back side of the second integrated circuit and the die paddle.

15. The system as claimed in claim 11 wherein the second molding compound comprises a seal with the second molding compound attached to the first molding compound.

16. The system as claimed in claim 11 wherein:
the lead frame having the die paddle has lead fingers;
the first integrated circuit includes a first back side of the first integrated circuit; p1 the first electrical interconnects between the first integrated circuit and the lead frame includes the first electrical interconnects between a first active side of the first integrated circuit and the lead frame;
the first molding compound to cover the first integrated circuit and the first electrical interconnects also covers a top surface of the inner portion of the lead frame;
the second integrated circuit to the first integrated circuit comprises a first back side of the first integrated circuit to a second back side of the second integrated circuit;
the second electrical interconnects between the second integrated circuit and the lead frame includes the second electrical interconnects between a second active side of the second integrated circuit and the lead frame; and
the second molding compound to cover the second integrated circuit and the second electrical interconnects comprises the second molding compound attached to the first molding compound.

17. The system as claimed in claim 16 further comprising horizontal dimensions of the first integrated circuit similar to horizontal dimensions of the second integrated circuit.

18. The system as claimed in claim 16 wherein the second molding compound comprises a thickness of the second molding compound less than a height of the lead fingers.

19. The system as claimed in claim 16 wherein the first electrical interconnects comprises bond wires.

20. The system as claimed in claim 16 wherein the second electrical interconnects comprises bond wires.
